(19) United States
(12) Patent Application Publication
(10) Pub. No.: US 2025/0197429 A1
(43) Pub. Date: Jun. 19, 2025

(54) TIN CONTAINING ORGANOMETALLIC COMPOUNDS

(71) Applicant: SEASTAR CHEMICALS ULC, Sidney (CA)

(72) Inventors: Diana FABULYAK, Victoria (CA); Cassidy CONOVER, Qualicum Beach (CA); Shaun CEMBELLA, Victoria (CA); Collin CAMPBELL, Victoria (CA)

(73) Assignee: SEASTAR CHEMICALS ULC, Sidney, BC (CA)

(21) Appl. No.: 18/846,958

(22) PCT Filed: Apr. 20, 2023
(86) PCT No.: PCT/IB2023/054018

§ 371 Date: Sep. 13, 2024

Related U.S. Application Data
(60) Provisional application No. 63/334,430, filed on Apr. 25, 2022.

(51) Int. Cl. C07F 7/22; C07F 15/04

(52) U.S. Cl. CPC C07F 7/2208; C07F 7/2284; C07F 15/04

(57) ABSTRACT

Specific organometallic compounds of Formula I: (R)ₓSn(A)₄₋ₓ, wherein R is selected from unsaturated hydrocarbons and A is selected from amine groups, alkoxy groups, and halides, as well as highly purified forms of the organometallic compounds.

### CROSS-REFERENCE TO RELATED APPLICATIONS

This application claims priority to U.S. Provisional Application No. 63,334,430 filed Apr. 25, 2022, which is incorporated herein in its entirety.

### TECHNICAL FIELD

The present disclosure relates to organometallic compounds useful for the deposition of high purity tin oxide and highly purified forms of the organometallic compounds. More specifically, the present disclosure describes specific compounds useful in deposition of high purity tin oxide as well as compositions that result in improved reactivity and better stability.

### BACKGROUND

Extreme ultraviolet (EUV) lithography enables a superb resolution of patterns that have been transferred onto a wafer substrate to form microchips. Unfortunately, traditional chemical amplified resists are highly transparent at an EUV wavelength of 13.5 nm (92 eV). Thus, there is a need in the industry to develop a new generation of photosensitive materials to enable production of smaller microchips for an array of technical applications.

One strategy to increase the sensitivity of photosensitive materials is an incorporation of atoms with enhanced absorptivity in the EUV regime, such as Sn, into the resist composition. Thus, there is a desire for Sn organometallics having high reactivity and stability for use as photo-sensitive materials in EUV processes and deposition processes.

### SUMMARY

Applicant determined that decreasing the bond energy of the Sn-C bond could improve performance of the Sn photosensitive materials in certain uses (photolytic cleavage of Sn-C bonds during exposure to EUV would promote cross-linking hence making these materials superior negative photoresist). Ligands containing unsaturated hydrocarbons, such as allyl, may provide decreased bond energy of the Sn-C bond.

Despite the foregoing advantages of decreasing the bond energy of the Sn-C bond in photosensitive materials, it is also contemplated that strengthening the Sn-C bond in photosensitive materials may also be advantageous in photosensitive materials in other uses. Ligands containing unsaturated hydrocarbons, such as vinyl, may provide increased bond energy of the Sn-C bond. By strengthening the Sn-C bond, some ligands bonded to Sn may be retained in the deposited film for further EUV treatment, which may be advantageous in particular uses.

In addition, amino, alkoxy, or halide ligands enable reactivity with OH groups of wafers/substrate layers for effective ALD deposition. Thus, Applicant discovered that organometallics of tin having a combination of ligands containing unsaturated hydrocarbons and ligands containing amino, alkoxy, or halide ligands have improved properties for deposition, especially atomic layer deposition, and for use as a photosensitive material in patterning applications.

In one aspect, disclosed are organometallic compounds of Formula I, below:
(R)ₓSn(A)₄₋ₓ Formula I
wherein:
R is substituted Cp, unsubstituted Cp, or a non-cyclic unsaturated hydrocarbon having 2 to 10 carbon atoms, or 2 to 8 carbon atoms, or 2 to 4 carbon atoms;
A is NR¹R², OR^{3,} pyrrolidinyl, pyrrolyl, or halide;
R¹ and R² are each an alkyl group having from 1 to 10 carbon atoms;
R¹ and R² can be the same or different;
R³ is an alkyl group having 2 to 8 carbon atoms;
x is an integer from 1 to 3; and
when A is NR¹R², pyrrolidinyl, pyrrolyl, or halide, R is substituted Cp or a non-cyclic unsaturated hydrocarbon having 2 to 10 carbon atoms, or 2 to 8 carbon atoms, or 2 to 4 carbon atoms.

In embodiments, R is an allyl or vinyl group. In some embodiments, the allyl or vinyl group can be straight chain. Alternatively, the allyl group can be a substituted allyl group having the general formula: CR⁴R⁵CR⁶═CR⁷R⁸, wherein R⁴, R⁵, R⁶, R⁷, and R⁸ are each independently selected from the group consisting of H and alkyl groups having from 1 to 4 carbon atoms. Similarly, the vinyl group can be a substituted vinyl group having the general formula: CR⁹═CR¹⁰R¹¹, wherein R⁹, R¹⁰, and R¹¹ are each independently selected from the group consisting of H and alkyl groups having from 1 to 4 carbon atoms.

In other embodiments, R is Cp, which is a cyclopentadienyl group having R¹², R¹³, R¹⁴, R¹⁵, and R¹⁶ constituents. Depending on A, Cp can be substituted or unsubstituted. R¹², R¹³, R¹⁴, R¹⁵, and R¹⁶ each independently selected from H and an alkyl group having from 1 to 10 carbon atoms, such as methyl, ethyl, propyl, butyl, pentyl, hexyl, heptyl, octyl, nonyl, or decyl. R¹², R¹³, R¹⁴, R¹⁵, and R¹⁶ can be the same or different. However, when A is NR¹R², pyrrolidinyl, pyrrolyl, or halide, at least one of R¹², R¹³, R¹⁴, R¹⁵, and R¹⁶ is an alkyl group having from 1 to 10 carbon atoms.

In any of the above-mentioned embodiments, A is NR¹R². In such embodiments, R¹ and R² are independently selected from an alkyl group having from 1 to 4 carbon atoms. In embodiments R¹ and R² are methyl or ethyl. In embodiments R¹ and R² are different.

Alternatively, A can be OR³. In such embodiments R³ is an alkyl group having from 1 to 4 carbon atoms. In embodiments R³ is methyl, ethyl, or tert-butyl. In other embodiments, A is one of pyrrolyl, pyrrolidinyl, or halide.

In embodiments, the organometallic compound is selected from the group consisting of (CH₂═CHCH₂)Sn(NMe₂)₃, (CH₂═CHCH₂)Sn(NEt₂)₃, (CH₂═CHCH₂)Sn(NEtMe)₃, (CH₂═CHCH₂)Sn(Pyrrolidinyl)₃, (CH₂═CH)Sn(NMe₂)₃, (CH₂═CH)Sn(NEt₂)₃, (CH₂═CH)Sn(NEtMe)₃, (CH₂═CH)Sn(Pyrrolidinyl)₃, (Cp)Sn(NMe₂)₃, (Cp)Sn(NEt₂)₃, (Cp)Sn(NEtMe)₃, (Cp)Sn(Pyrrolidine)₃, (CH₂═CHCH₂)₂Sn(NMe₂)₂, (CH₂═CHCH₂)₂Sn(NEt₂)₂, (CH₂═CHCH₂)₂Sn(NEtMe)₂, (CH₂═CHCH₂)₂Sn(Pyrrolidine)₂, (CH₂═CH)₂Sn(NMe₂)₂, (CH₂═CH)₂Sn(NEt₂)₂, (CH₂═CH)₂Sn(NEtMe)₂, (CH₂═CH)₂Sn(Pyrrolidine)₂, (Cp)₂Sn(NMe₂)₂, (Cp)₂Sn(NEt₂)₂, (Cp)₂Sn(NEtMe)₂, (Cp)₂Sn(Pyrrolidine)₂, (CH₂═CHCH₂)₃Sn(NMe₂), (CH₂═CHCH₂)₃Sn(NEt₂), (CH₂═CHCH₂)₃Sn(NEtMe), (CH₂═CHCH₂)₃Sn(Pyrrolidine), (CH₂═CH)₃Sn(NMe₂), (CH₂═CH)₃Sn(NEt₂), (CH₂═CH)₃Sn(NEtMe), (CH₂═CH)₃Sn(Pyrrolidine), (Cp)₃Sn(NMe₂), (Cp)₃Sn(NEt₂), (Cp)₃Sn(NEtMe), (Cp)₃Sn(Pyrrolidine).

### BRIEF DESCRIPTION OF THE DRAWINGS

Embodiments of the invention will now be described by way of example with reference to the accompanying drawings, of which:

FIG. 1 shows a ¹H NMR spectrum of a reaction mixture comprising (CH₂═CHCH₂)Sn(Cl)₃ in toluene (300 MHz, C₆D₆).

FIG. 2 shows a ¹¹⁹Sn NMR spectrum of a reaction mixture comprising (CH₂═CHCH₂)Sn(Cl)₃ in toluene (186.55 MHz, C₆D₆).

FIG. 3 shows a ¹H NMR spectrum of a reaction mixture comprising (CH₂═CHCH₂)₂Sn(Cl)₂ in toluene (300 MHz, C₆D₆).

FIG. 4 shows a ¹H NMR spectrum of an isolated product mixture comprising (CH₂═CHCH₂)Sn(NMe₂)₃, (CH₂═CHCH₂)₂Sn(NMe₂)₂, and (CH₂═CHCH₂)₃Sn(NMe₂) after 12 hours at 22° C. (300 MHz, C₆D₆).

FIG. 5 shows a ¹¹⁹Sn NMR spectrum of an isolated product mixture comprising (CH₂═CHCH₂)Sn(NMe₂)₃, (CH₂═CHCH₂)₂Sn(NMe₂)₂, and (CH₂═CHCH₂)₃Sn(NMe₂) after 12 hours at 22° C. (187 MHz, C₆D₆).

FIG. 6 shows a ¹H NMR spectrum of a product mixture comprising (CH₂═CHCH₂)₂Sn(NiPr₂)₂ and HNiPr₂ (300 MHz, C₆D₆).

FIG. 7 shows a ¹H NMR spectrum of (CH₂═CH)₃Sn(NEt₂) (500 MHz C₆D₆).

FIG. 8 shows a ¹H NMR spectrum of (CH₂═CH)₃Sn (NEt₂) (186 MHz C₆D₆).

FIG. 9 shows a vapor pressure curve of (CH₂═CH)₃Sn(NEt₂).

FIG. 10 shows a ¹¹⁹Sn NMR spectrum of Cp^{iPr}Sn(NMe₂)₃(186 MHz, C₆D₆).

FIG. 11A shows a cross section of a deposited intermediate product.

FIG. 11B shows a cross section of a developed intermediate product.

FIG. 11C shows a cross section of an etched intermediate product.

FIG. 11D shows a cross section of a final product.

FIG. 12 shows a schematic of a multistage vacuum distillation apparatus.

### DETAILED DESCRIPTION

Before describing several exemplary embodiments, it is to be understood that the invention is not limited to the details of construction or process steps set forth in the following description. The invention is capable of other embodiments and of being practiced or being carried out in various ways.

Reference throughout this specification to “one embodiment,” “certain embodiments,” “one or more embodiments” or “an embodiment” means that a particular feature, structure, material, or characteristic described in connection with the embodiment is included in at least one embodiment. Thus, the appearances of the phrases such as “in one or more embodiments,” “in certain embodiments,” “in one embodiment” or “in an embodiment” in various places throughout this specification are not necessarily referring to the same embodiment. Furthermore, the particular features, structures, materials, or characteristics may be combined in any suitable manner in one or more embodiments.

Although reference herein is to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

Reference throughout this specification to “a” or “an” represents one or more and is not limited to singular form, unless explicitly stated.

The following detailed description can be read in connection with the accompanying drawings in which like numerals designate like elements.

Disclosed are organometallic compounds of Formula I, below:
(R)ₓSn(A)₄₋ₓ Formula I
wherein:
R is substituted Cp, unsubstituted Cp, or a non-cyclic unsaturated hydrocarbon having 2 to 10 carbon atoms, or 2 to 8 carbon atoms, or 2 to 4 carbon atoms;
A is NR¹R², OR³, pyrrolidinyl, pyrrolyl, or halide;
R¹and R²are each an alkyl group having from 1 to 10 carbon atoms;
R¹ and R² can be the same or different;
R³ is an alkyl group having 2 to 8 carbon atoms;
x is an integer from 1 to 3; and
when A is NR¹R², pyrrolidinyl, pyrrolyl, or halide, R is substituted Cp or a non-cyclic unsaturated hydrocarbon having 2 to 10 carbon atoms, or 2 to 8 carbon atoms, or 2to 4 carbon atoms.

Also disclosed are high-purity organometallic compounds and methods of purifying the organometallic compounds.

Applicant discovered that during synthesis of compounds of Formula I, dissociation occurred. For example, molecules of (CH₂═CHCH₂)₂Sn(NMe₂)₂, a product, underwent significant ligand exchange, resulting in the formation of side products, such as (CH₂═CHCH₂)Sn(NMe₂)₃ and (CH₂═CHCH₂)₃Sn(NMe₂). It is contemplated that bulkier ligands, such as substituted allyl, substituted vinyl, substituted or unsubstituted Cp, which is cyclopentadienyl, heavier amines, or heavier alkoxies in the compound of Formula I may be able to prevent side product creation and improve stability by reducing ligand exchange.

In embodiments, R is an allyl group having the general formula: CR⁴R⁵CR⁶═CR⁷R⁸, wherein R⁴, R⁵, R⁶, R⁷, and R⁸ are each independently selected from the group consisting of H and alkyl groups having from 1 to 4 carbon atoms, such as methyl, ethyl, propyl, iso-propyl, tert-butyl, iso-butyl, or n-butyl. R4, R⁵, R⁶, R⁷, and R⁸ can be the same or different. In embodiments, at least one of R⁴ and R⁵ is not H, such as 1,1-dimethylallyl, wherein R⁴ and R⁵ are both methyl. In embodiments R⁶ is not H, such as 2-methylallyl. In embodiments at least one of R⁷ and R⁸ is not H, such as 3,3-dimethylallyl. In some embodiments, x is 2 and compounds of Formula I are represented by the following formula: (CR⁴R⁵CR⁶═CR⁷R⁸)₂Sn(A)₂, wherein A is NR¹R², OR³, pyrrolidinyl, pyrrolyl, or halide.

In other embodiments, R is a vinyl group having the general formula: CR⁹═CR¹⁰0R¹¹, wherein R⁹, R¹⁰, and R¹¹are each independently selected from the group consisting of H and alkyl groups having from 1 to 4 carbon atoms, such as methyl, ethyl, propyl, iso-propyl, tert-butyl, iso-butyl, or n-butyl. R⁹, R¹⁰, and R¹¹ can be the same or different. In embodiments, R⁹ is not H, such as 1-ethylvinyl. In embodiments at least one of R¹⁰ and R¹¹ is not H, such as 2,2-dimethylvinyl. In some embodiments, x is 2 and compounds of Formula I are represented by the following formula: (CR⁹═CR¹⁰R¹¹)₂Sn(A)₂, wherein A is NR¹R², OR³, pyrrolidinyl, pyrrolyl, or halide.

Any of the above-mentioned compounds of Formula I include those in which x is 1. In such embodiments, Compounds of Formula I are represented by the following formula: (R)Sn(A)₃, wherein R is a non-cyclic unsaturated hydrocarbon having 2 to 10 carbon atoms.

Compounds of Formula I also include those in which x is 3. In such alternative embodiments, compounds of Formula I are represented by the following formula: (R)₃Sn(A), wherein R is a non-cyclic unsaturated hydrocarbon having 2 to 10 carbon atoms.

Any of the above-mentioned compounds of Formula I represented by the formula: (R)ₓSn(A)₄₋ₓ include those in which R is a non-cyclic unsaturated hydrocarbon having 2 to 8 carbon atoms. Further, Compounds of Formula I include those in which R is a non-cyclic unsaturated hydrocarbon having 2 to 4 carbon atoms.

Any of the above-mentioned compounds of Formula I include those in which A is NR¹R². R¹ and R² are independently selected from H, alkyl groups having from 1 to 10 carbon atoms, aryl groups, or acyl groups. R¹ and R² can be the same or different. In a particular embodiment, R¹ and R² are each alkyl groups having 1 to 10 carbons atoms. In a more particular embodiment, R¹ and R² are each alkyl groups having from 2 to 4 carbon atoms. More particularly, R¹ and R² can each be selected from the group consisting of methyl, ethyl, propyl, iso-propyl, tert-butyl, iso-butyl, and n-butyl.

For any of the above-mentioned compounds, it is contemplated that R can be either a straight-chain unsaturated hydrocarbon or a branched unsaturated hydrocarbon.

Any of the above-mentioned compounds of Formula I also include those in which A is OR³. In such embodiments, compounds of Formula I are represented by the formula: (R)ₓSn(OR³)₄₋ₓ, wherein R³ is an alkyl group having 2 to 8 carbon atoms. In other embodiments, R³ is selected from the group consisting of an alkyl group having from 1 to 4 carbon atoms. More particularly, R³ can be selected from the group consisting of methyl, ethyl, propyl, iso-propyl, tert-butyl, iso-butyl, and n-butyl.

When A is an alkoxy group, such as OR³, R can be Cp. In such embodiments, compounds of Formula I are represented by the formula: (Cp)ₓSn(OR³)₄₋ₓ, wherein Cp is a cyclopentadienyl group having R¹², R¹³, R¹⁴, R¹⁵, and R¹⁶ constituents. Cp can be unsubstituted, wherein R¹², R¹³, R¹⁴, R¹⁵, and R¹⁶ are H, or substituted, wherein at least one of R¹², R¹³, R¹⁴, R¹⁵, and R¹⁶ is independently selected from an alkyl group having from 1 to 10 carbon atoms, such as methyl, ethyl, propyl, butyl, pentyl, hexyl, heptyl, octyl, nonyl, or decyl. R¹², R¹³, R¹⁴, R¹⁵, and R¹⁶ can be the same or different.

When A is an amine group, such as NR¹R², or pyrrolidinyl, pyrrolyl, or halide, R can be substituted Cp, wherein at least one of R¹², R¹³, R¹⁴, R¹⁵, and R¹⁶ is independently selected from an alkyl group having from 1 to 10 carbon atoms, such as methyl, ethyl, propyl, butyl, pentyl, hexyl, heptyl, octyl, nonyl, or decyl. R¹², R¹³, R¹⁴, R¹⁵, and R¹⁶ can be the same or different.

Compounds of Formula I include those in which A is pyrrolidinyl or pyrrolyl. Such embodiments are respectively represented by the general formula: (R)ₓSn(Pyrrolidinyl)₄₋ₓ or (R)ₓSn(Pyrrolyl)₄₋ₓ. It is contemplated that A could also be a halide, such as chloro, bromo, or iodo.

When R is Cp, compounds of Formula I, (Cp)ₓSn(A)₄₋ₓ may be synthesized as follows. In a glovebox, load a 1 L round bottom flask with SnCl₄ and anhydrous hexanes. Add 1 equiv. of NaCp* (NaC₅Me₅) drop-wise while cooling. Leave the reaction mixture stirring at room temperature for 1 hour. Return the reaction flask into a cooling bath and add 3 equiv. of NaOMe in anhydrous THF to the flask. Remove solvents via reduced pressure distillation. Isolate the product via sublimation.

Particular organometallic compounds of Formula I include the following: (CH₂═CHCH₂)Sn(NMe₂)₃, (CH₂═CHCH₂)Sn(NEt₂)₃, (CH₂═CHCH₂)Sn(NEtMe)₃, (CH₂═CHCH₂)Sn(Pyrrolidinyl)₃, (CH₂═CH)Sn(NMe₂)₃, (CH₂═CH)Sn(NEt₂)₃, (CH₂═CH)Sn(NEtMe)₃, (CH₂═CH)Sn(Pyrrolidinyl)₃, (Cp)Sn(NMe₂)₃, (Cp)Sn(NEt₂)₃, (Cp)Sn(NEtMe)₃, (Cp)Sn(Pyrrolidine)₃, (CH₂═CHCH₂)₂Sn(NMe₂)₂, (CH₂═CHCH₂)₂Sn(NEt₂)₂, (CH₂═CHCH₂)₂Sn(NEtMe)₂, (CH₂═CHCH₂)₂Sn(Pyrrolidine)₂, (CH₂═CH)₂Sn(NMe₂)₂, (CH₂═CH)₂Sn(NEt₂)₂, (CH₂═CH)₂Sn(NEtMe)₂, (CH₂═CH)₂Sn(Pyrrolidine)₂, (Cp)₂Sn(NMe₂)₂, (Cp)₂Sn(NEt₂)₂, (Cp)₂Sn(NEtMe)₂, (Cp)₂Sn(Pyrrolidine)₂, (CH₂═CHCH₂)₃Sn(NMe₂), (CH₂═CHCH₂)₃Sn(NEt₂), (CH₂═CHCH₂)₃Sn(NEtMe), (CH₂═CHCH₂)₃Sn(Pyrrolidine), (CH₂═CH)₃Sn(NMe₂), (CH₂═CH)₃Sn(NEt₂), (CH₂═CH)₃Sn(NEtMe), (CH₂═CH)₃Sn(Pyrrolidine), (Cp)₃Sn(NMe₂), (Cp)₃Sn(NEt₂), (Cp)₃Sn(NEtMe), (Cp)₃Sn(Pyrrolidine).

Decreasing the bond strength of the Sn-C bond could improve performance of the Sn photosensitive materials during photolytic cleavage of Sn-C bonds upon exposure to EUV. It would promote cross-linking hence making these materials superior negative photoresist. Unsaturated hydrocarbons, such as allyl ligands, are great compounds for this application. Additionally, the presence of a Sn-allyl bond would improve the reactivity of this molecule during SnO₂ film formation.

Increasing the bond strength of the Sn-C bond may also be advantageous in photosensitive materials. Ligands containing unsaturated hydrocarbons, such as vinyl, may provide increased bond energy of the Sn-C bond. By strengthening the Sn-C bond, some ligands bonded to Sn may be retained in the deposited film for further EUV treatment, which may be advantageous.

Compounds of Formula I may be prepared by processes known in the art. The examples below are illustrative of such processes but are not intended to be limiting.

### Example 1: Synthesis of (CH₂═CHCH₂)Sn(Cl)₃

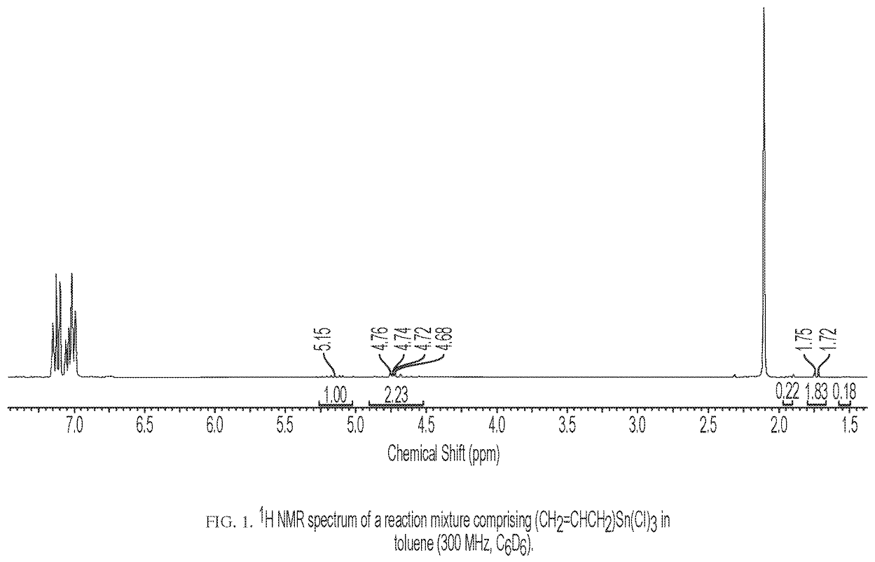

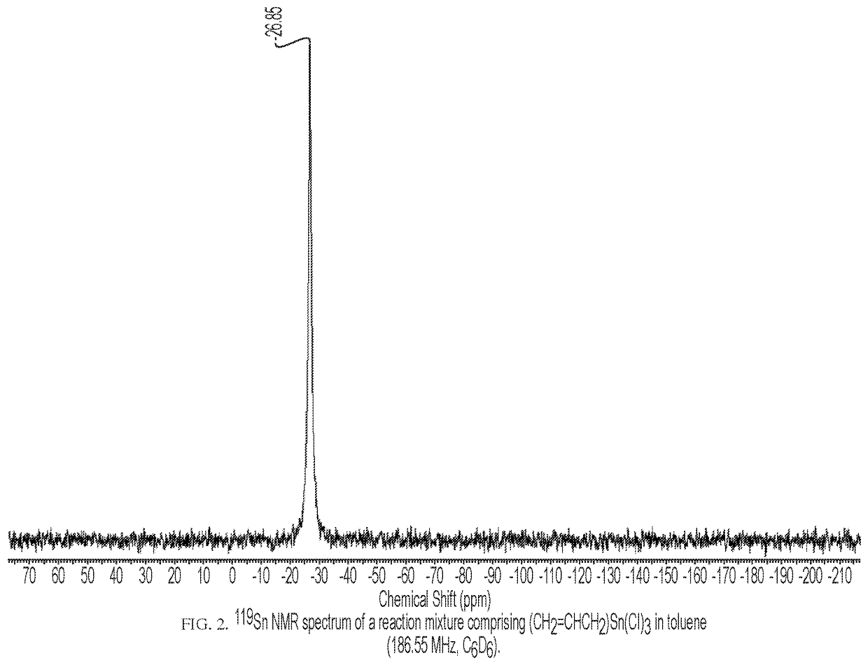

On a double manifold, a small Schlenk flask was loaded with 6.0 mL of SnCl₄ (51 mmol), ca. 60 mL of anhydrous toluene, and a magnetic stir bar. While stirring at room temperature, 4.1 mL of Sn(allyl)₄ (17mmol) was added drop-wise. The reaction mixture was stirred at 22° C. for 90 minutes. A small aliquot was collected for ¹H NMR and ¹¹⁹Sn NMR analysis and confirmed the formation of (CH₂═CHCH₂)Sn(Cl)₃ as shown in FIGS. 1 and 2. Removal of the solvent may affect stability. Characterization: ¹H NMR (300 MHz, C₆D₆) (FIG. 1): 1.72 ppm (m, ²J^{H119Sn}=120 Hz, ²J_{H117Sn}=124 Hz, 1H, allyl CH₂), 1.75 ppm (m, ²J_{H119Sn}=118 Hz, ²J_{H1175n}=124 Hz, 1H, allyl CH₂), 4.69 ppm (m, ³J_{HH}=16.6 Hz, 1H, allyl CH₂), 4.74 ppm (m, ³J_{HH}=9.7 Hz, 1H, allyl CH₂), 5.15 ppm (m, 1H, allyl CH). ¹¹⁹Sn NMR (186.55 MHz, C₆D₆) (FIG. 2): −26.8 ppm.

### Example 2: Synthesis of (CH₂═CHCH₂)₂Sn(Cl)₂

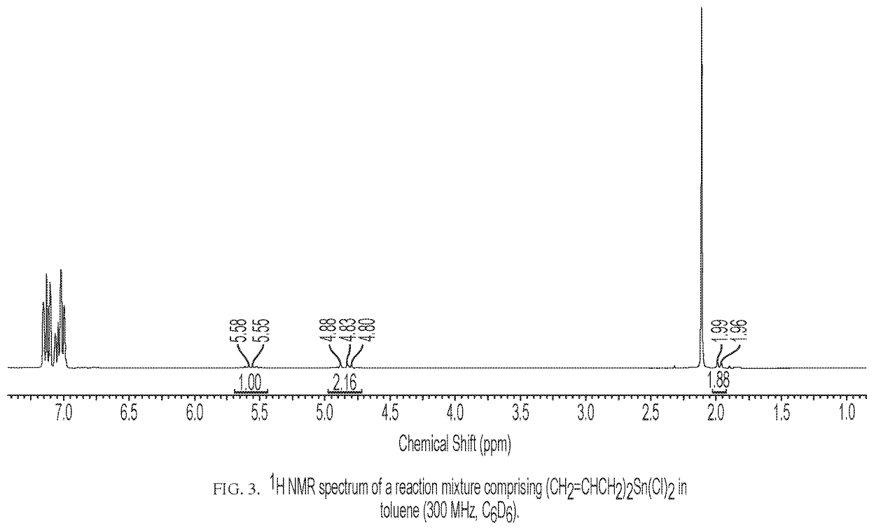

On a double manifold, a small Schlenk flask was loaded with 2.0 mL of SnCl₄ (17mmol), ca. 30mL of anhydrous toluene, and a magnetic stir bar. While stirring at room temperature, 4.1 mL of Sn(allyl)₄ (17mmol) was added drop-wise. The reaction mixture was stirred at 22° C. for 90 minutes. A small aliquot was collected for ¹H NMR and ¹¹⁹Sn NMR analysis and confirmed the formation of (CH₂═CHCH₂)₂Sn(Cl)₂ as shown in FIG. 3. Removal of the solvent may affect stability. Characterization: ¹H NMR (300 MHz, C₆D₆) (FIG. 3): 1.96 ppm (m, 1H, allyl CH₂), 1.99 ppm (m, 1H, allyl CH₂), 4.80-4.88 ppm (m, 2H, allyl CH₂), 5.57 ppm (m, 1H, allyl CH). ¹¹⁹Sn NMR (186.55 MHz, C₆D₆): 48.3 ppm.

### Example 3: Synthesis of (CH₂═CHCH₂)₂Sn(NMe₂)₂

On a double manifold, a 1 L round bottom flask was loaded with 82 mL of BuLi (2.5M in hexanes, 0.205 mol), ca. 500 mL of anhydrous toluene and a magnetic stir bar. The flask was placed in an ice-water bath and HNMez was bubbled through the reaction mixture for 20 minutes at a rate of 284 mL per minute (0.251 mol). The reaction flask was removed from the cooling bath and left to stir at 22° C. for 90 minutes.

Meanwhile, (CH₂═CHCH₂)₂Sn(Cl)₂ was prepared by reacting 6.0 mL of SnCl₄ (0.051 mol) in ca. 100 mL of anhydrous toluene and 12.3 mL of Sn(allyl)₄ (0.051 mol). This reaction was stirred at 22° C. for 60 minutes. The flask containing (CH₂═CHCH₂)₂Sn(Cl)₂ was returned to an ice-water bath where an LiNMe₂ mixture was slowly added drop-wise via cannulation to the flask. The final reaction mixture was removed from the cooling bath and stirred at 22° C. for 50 minutes.

Stirring was stopped to allow the LiCl salts to settle down overnight. The next day, the liquid layer was transferred into a new round bottom flask. The solvent was removed via reduced pressure distillation. The final product was isolated via reduced pressure distillation (40° C. at 2.0-4.5×10⁻² Torr). A significant ligand exchange of (CH₂═CHCH₂)₂Sn(NMe₂)₂ has been detected resulting in the formation of (CH₂═CHCH₂)SN(NMe₂)₃ and (CH₂═CHCH₂)₃Sn(NMe₂) Eventually, the product distribution reaches 50:25:25 mol %.

### Characterization

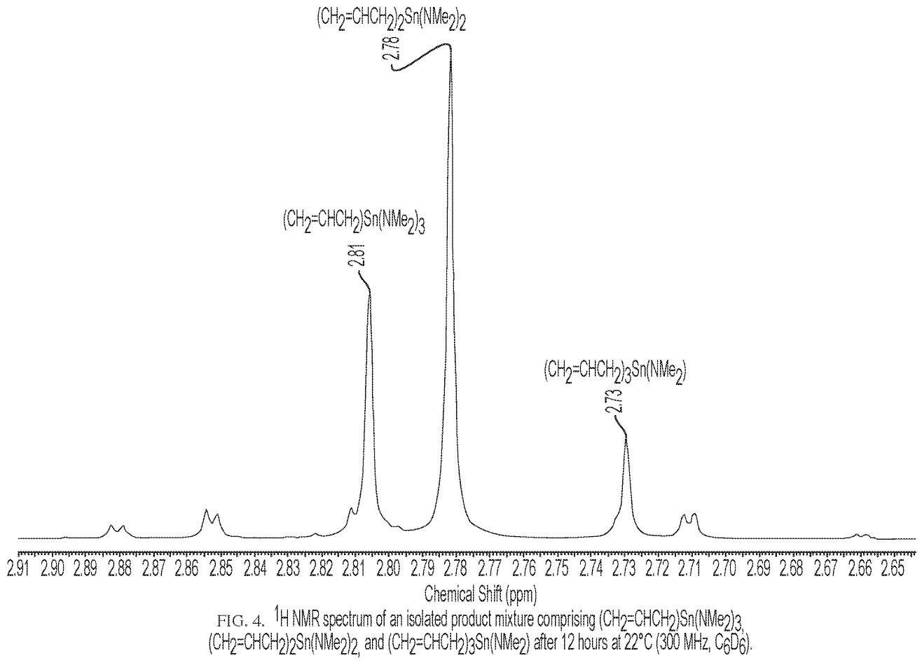

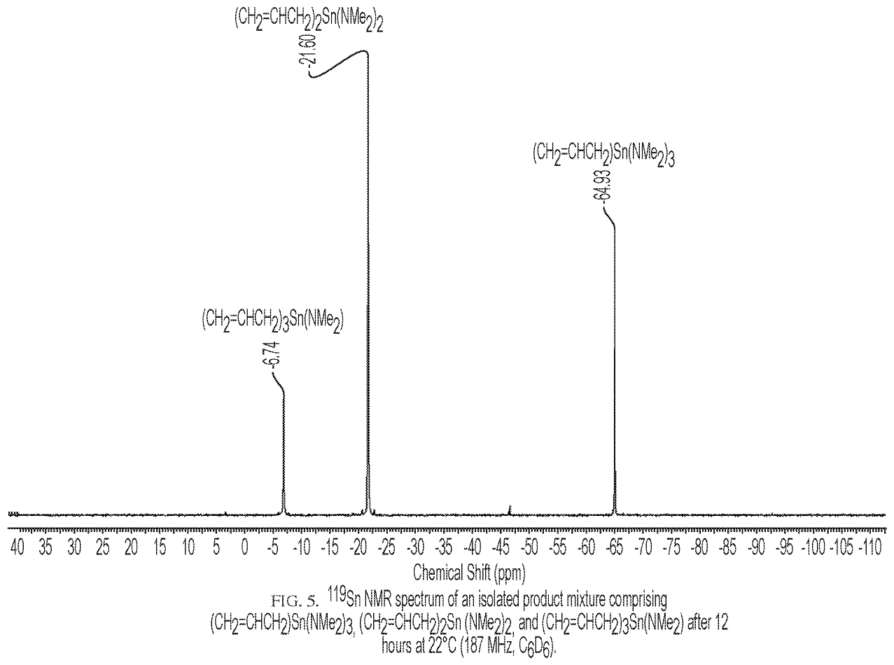

(CH₂═CHCH₂)₃Sn(NMe₂): ¹H NMR (300 MHz, C₆D₆) (FIG. 4): 1.87 ppm (dd, ²J_{HH}=1.2 Hz; ³J_{HH}=0.7 Hz, 3H, allyl CH₂), 1.90 ppm (dd, ²J_{HH}=1.2 Hz; 3 J_{HH}=0.7 Hz, 3H, allyl CH₂), 2.73 ppm (s, ³J_{H119Sn}=42.6 Hz, ³J_{H117Sn}=41.1 Hz, 6H, NMe₂), 4.82 ppm (m, 3H, allyl CH₂), 4.93 ppm (ddd, ³J_{HH}=16.8 Hz, ⁴J_{HH}=3.2 Hz, ²J_{HH}=1.2 Hz; 3H, allyl CH₂), 5.9 ppm (m, 3H, allyl CH). ¹¹⁹Sn NMR (186.55 MHz, C₆D₆) (FIGS. 5): −6.9 ppm.

(CH₂═CHCH₂)₂Sn(NMe₂)₂: ¹H NMR (300 MHz, C₆D₆) (FIG. 4): 1.92 ppm (dd, ²J_{HH}=1.2 Hz; ³J_{HH}=0.7 Hz, 2H, allyl CH₂), 1.94 ppm (dd, ²J_{HH}=1.2 Hz; ³J_{HH}=0.7 Hz, 2H, allyl CH₂), 2.78 ppm (s, ³J_{H119Sn}=43.6 Hz, ³J_{H117Sn}=41.6 Hz, 12H, NMe₂), 4.83 ppm (m, 2H, allyl CH₂), 4.97 ppm (ddd, ³J_{HH}=16.8 Hz, ⁴J_{HH}=3.0 Hz, ²J_{HH}=1.2 Hz; 2H, allyl CH₂), 5.9 ppm (m, 2H, allyl CH). ¹¹⁹Sn NMR (186.55 MHz, C₆D₆) (FIGS. 5): −21.6 ppm.

(CH₂═CHCH₂)Sn(NMe₂)₃: ¹H NMR (300 MHz, C₆D₆) (FIG. 4): 1.93ppm (dd, ²J_{HH}=1.5 Hz; ³J_{HH}=1.0 Hz, 1H, allyl CH₂), 1.95 ppm (dd, ²J_{HH}=1.5 Hz; ³J_{HH}=1.0 Hz, 1H, allyl CH₂), 2.81 ppm (s, ³J_{H119Sn}=46.1 Hz, ³J_{H117Sn} =44.1 Hz, 18H, NMe₂), 4.83 ppm (m, ³J_{HH}=9.9 Hz, 1H, allyl CH₂), 4.97 ppm (ddd, ³J_{HH}=16.8 Hz, ⁴J_{HH}=3.0 Hz, ²J_{HH}=1.2 Hz; 1H, allyl CH₂), 5.9 ppm (m, 1H, allyl CH). ¹¹⁹Sn NMR (186.55 MHz, C₆D₆) (FIGS. 5): −64.9 ppm.

Example 4: Synthesis of (CH₂═CHCH₂)₂Sn(NEt₂)₂

On a double manifold, a Schlenk flask was loaded with 27.5 mL of nBuLi (2.5M in hexanes, 0.069 mol), ca. 125 mL of anhydrous toluene and a magnetic stir bar. The flask was placed in an ice-water bath and HNEt₂ (7.4 mL, 0.072 mol) in ca. 20 mL of anhydrous toluene was added to the reaction flask drop-wise. The reaction flask was removed from the cooling bath and left to stir at 22° C. for 40 minutes.

Meanwhile, (CH₂═CHCH₂)₂Sn(Cl)₂ was prepared by reacting 2.0 mL of SnCl₄ (0.017 mol) in ca. 80 mL of anhydrous toluene and 4.1 mL of Sn(allyl)₄ (0.017 mol). This reaction was stirred at 22° C. for 60 minutes. The flask containing (CH2 ═CHCH₂)₂Sn(Cl)₂ was returned to an ice-water bath and the LiNMe₂ mixture was slowly added drop-wise via cannulation to the flask. The final reaction mixture was removed from the cooling bath and stirred at 22° C. for 30 minutes before proceeding with distillation under reduced pressure to removed solvent and collect the product (80° C. at 0.05 Torr).

Characterization: ¹H NMR (300 MHz, C₆D₆): 1.08 ppm (t, ³J_{HH}=6.9 Hz, 12H, N(CH₂CH₃)), 1.95 ppm (dd, ²J_{HH}=1.5 Hz; ³J_{HH}=1.0 Hz, 2H, allyl CH₂), 1.98 ppm (dd, ²J_{HH}=1.5Hz; ³J_{HH}=1.0 Hz, 2H, allyl CH₂), 3.04 ppm (q, ³J_{HH}=6.9 Hz, 8H, N(CH₂CH₃)), 4.86 ppm (m, 2H, allyl CH₂), 4.98 ppm (m, 2H, allyl CH₂), 5.9 ppm (m, 2H, allyl CH). ¹¹⁹Sn NMR (134.35 MHz, C₆D₆): −24.8 ppm.

Example 5: Synthesis of (CH₂═CHCH₂)₂Sn(NiPr₂)₂

On a double manifold, a 1 L round bottom flask was loaded with 29.9 mL of nBuLi (2.5M in hexanes, 0.075 mol), ca. 500 mL of anhydrous toluene and a magnetic stir bar. The flask was placed in an ice-water bath and HNiPr₂ (11 mL, 0.079 mol) in ca. 20 mL of anhydrous toluene was added to the reaction flask drop-wise. The reaction flask was removed from the cooling bath and left to stir at 22° C. overnight. The reaction flask was then transferred into the ice-water bath.

Meanwhile, (CH₂═CHCH₂)₂Sn(Cl)₂ was prepared by reacting 2.19 mL of SnCl₄ (0.019 mol) in ca. 100 mL of anhydrous toluene and 4.49 mL of Sn(allyl)₄ (0.019 mol). This reaction was stirred at 22° C. for 3h. The (CH₂═CHCH₂)₂Sn(Cl)₂ mixture was slowly added drop-wise to the round bottom flask via cannulation. The final reaction mixture was removed from the cooling bath and stirred at 22°° C. overnight. After removing solvents from the final product mixture, the product and some free amine in the residue have been characterized. This product is a solid and shows no signs of ligand exchange.

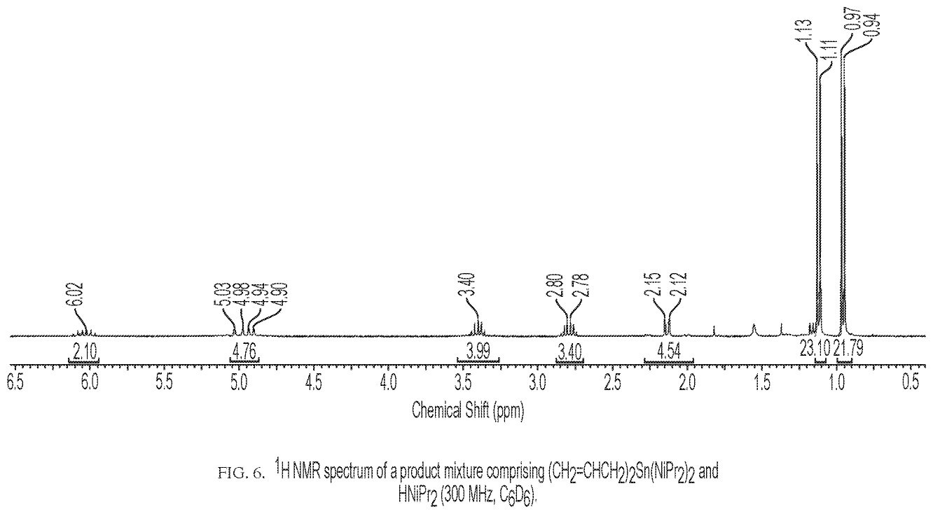

Characterization: ¹H NMR (300 MHz, C₆D₆) (FIG. 6): 0.89 ppm (d, ³J_{HH}=6.7 Hz, 24H, iPr-CH₃), 1.89 ppm (dd, ²J_{HH}=1.0 Hz; ³J_{HH}=1.2 Hz, 2H, allyl CH₂), 1.92 ppm (dd, ²J_{HH}=1.0 Hz; ³J_{HH}=1.2 Hz, 2H, allyl CH₂), 3.17 ppm (sept, ³J_{HH}=6.7 Hz, 4H, iPr-CH), 4.68 ppm (m, 2H, allyl CH₂), 4.78 ppm (m, 2H, allyl CH₂), 5.80 ppm (m, 2H, allyl CH).

Example 6: Synthesis of (CH₂═CH)₃SnCl

Synthesis of this complex was based on Sanders D. Rosenberg & Ambrose J. Gibbons Jr., The Disproportionation of Tetravinyltin with Tin Tetrachloride and the Cleavage of Some Vinyltin Compounds with Bromine, 79 J. AM. CHEM. SOC'Y. 2138 (1957), https://doi.org/10.1021/ja01566a029 [hereinafter Rosenberg & Gibbons]. This complex was not isolated and was used in the following salt metathesis reaction steps. Characterization: ¹H (300 MHz, C₆D₆): dd 5.77 ppm (³J_{HH}=2.7 Hz, ³J_{HH}=19.9 Hz, 3H, vinyl-CH), dd 5.98 ppm (³J_{HH}=2.7 Hz, ³J_{HH}=13.4 Hz, 3H, vinyl-CH), dd 6.14 ppm (³J_{HH}=13.4 Hz, ³J_{HH}=19.9 Hz, 3H, vinyl-CH). ¹¹⁹Sn (186 MHz, C₆D₆): s−53.8 ppm.

Example 7: Synthesis of (CH₂═CH)₃Sn(NEt₂)

On a double manifold, a 500 mL round bottom flask was loaded with 10.5 mL of nBuLi (2.5M in hexanes, 0.0263 mol), ca. 250 mL of anhydrous hexane and a magnetic stir bar. HNEt₂ (2.8 mL, 0.027 mol) was added to the reaction flask drop-wise. The reaction mixture was left to stir at 22° C. for 60 minutes.

Meanwhile, (CH₂═CH)₃SnCl was prepared by reacting 3.5 mL of Sn(vinyl)₄ (0.019 mol) and 0.8 mL of SnCl₄ (0.0068mol). This reaction was stirred at 40° C. for 90 minutes. See Rosenberg & Gibbons.

Proceed with a slow addition of (CH₂═CH)₃SnCl mixture into LiNEt₂ mixture via cannulation. The final reaction mixture was stirred at 22° C. overnight. Next day proceed with solvent removal via reduced pressure distillation followed by product collection in a separate receiving flask (0.08 Torr at 35° C.) to collect 5.2 g of the product (75% yield).

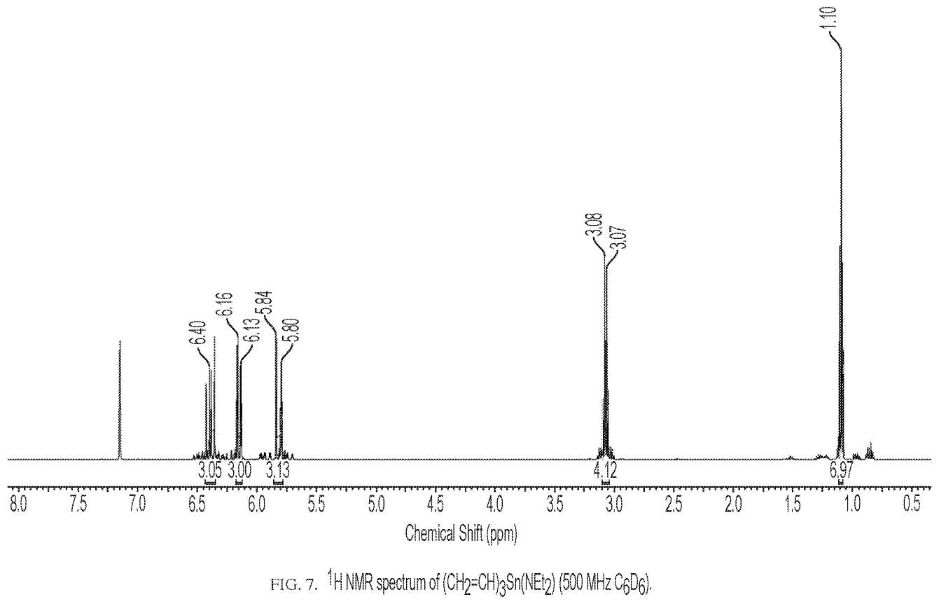

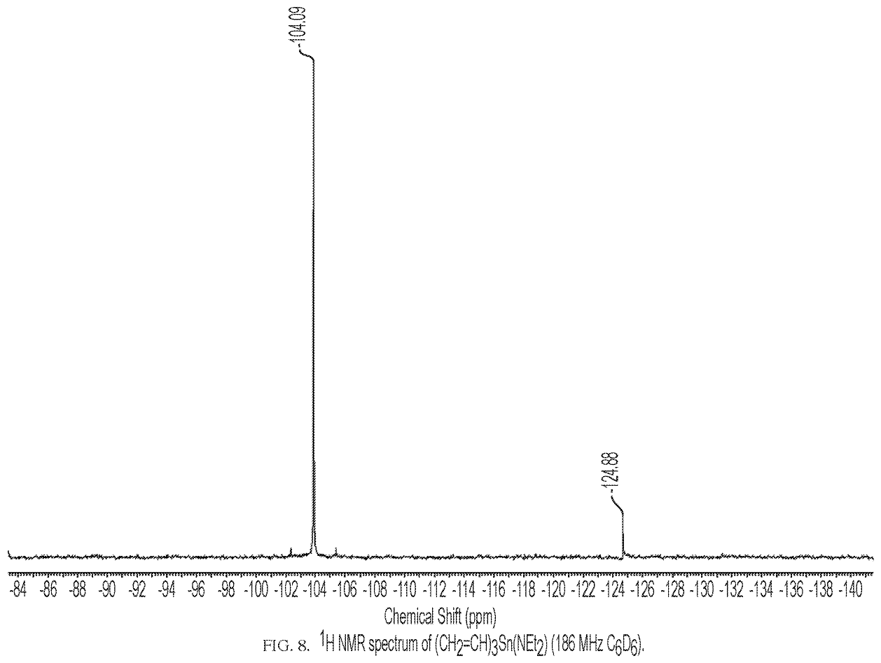

Characterization: ¹H (500 MHz, C₆D₆) (FIG. 7): t 1.10 ppm (³J_{HH}=6.9 Hz, 6H, NEt-CH₃), q 3.08 ppm (3 J_{HH}=6.9 Hz, 4H, NEt-CH₂), dd 5.82 ppm (³J_{HH}=3.2 Hz, ³J_{HH}=20.5 Hz, 3H, vinyl-CH), dd 6.16 ppm (³J_{HH}=3.2 Hz, ³J_{HH}=13.7 Hz, 3H, vinyl-CH), dd 6.40 ppm (³J_{HH}=13.7 Hz, ³J_{HH}+20.5 Hz, 3H, vinyl-CH). ¹¹⁹Sn (186 MHz, C₆D₆) (FIG. 8): s −104.1 ppm.

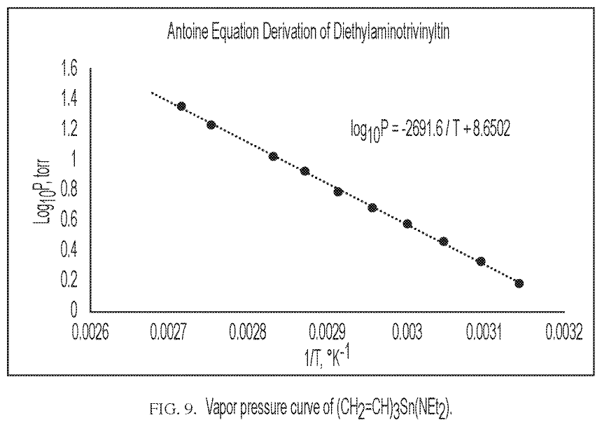

FIG. 9 shows a vapor pressure curve for (CH₂═CH)₃Sn(NEt₂). Vapor pressure measurements: log₁₀P=−2691.6/T+8.6502. The vapor pressure measurements were obtained as follows: A small amount of liquid is evaporated in a closed system with controllable temperature and pressure. At a set temperature, the pressure slowly drops until the liquid sample evaporates at a certain rate which is determined by measuring the drop rate of the liquid from a condenser directly above the liquid. This is repeated for 8-10 temperatures and run in duplicate. The results are compared with a side-by-side run of a calibration standard which helps adjust the pressure at the measured drop rate and temperature vs the known vapor pressure at that temperature.

### Example 8: Synthesis of Cp^{iPr}Sn(NMe₂)₃

In the glovebox, a small Schlenk flask was loaded with 1.2 mL of Sn (NMe₂)₄ (4.7 mmol) and ca. 13 mL of anhydrous THF. Add 0.679 g of NaCp^{iPr} (5.2 mmol). Transfer this Schlenk flask onto the double manifold and proceed with reflux at 76° C. for 4 hours. NMR analysis of the reaction mixture confirms formation of Cp^{iPr}Sn (NMe₂)₃. When isolated, this product is a solid.

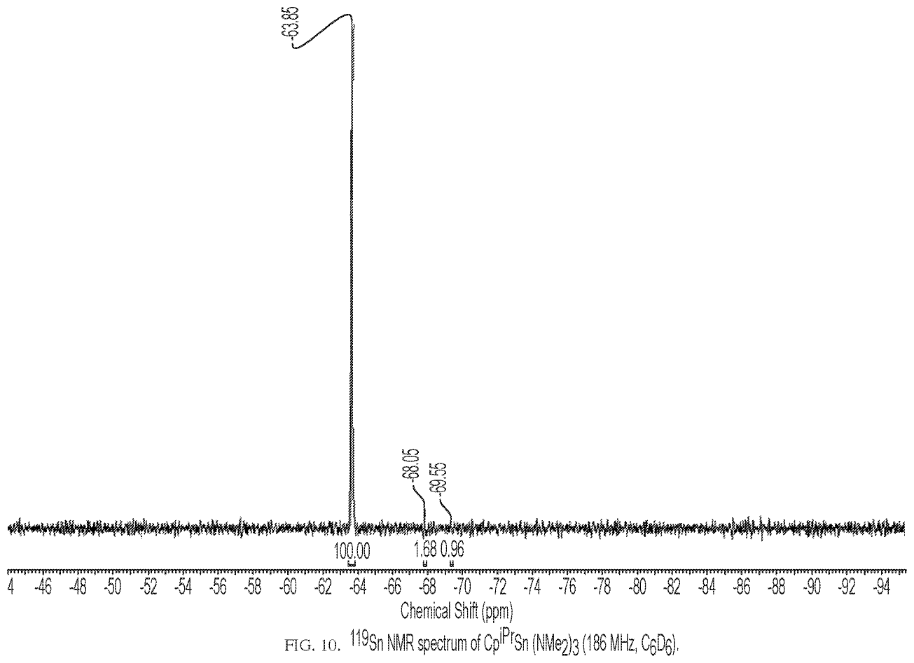

Characterization: ¹H (500 MHz, C₆D₆): d 1.36 ppm (³J_{HH}=6.7 Hz, 6H, iPr-CH₃), s 3.06 ppm (³J_{H119Sn}=42.1 Hz, ³J_{H117Sn}=40.4 Hz, 18H, NMe₂), sept 3.18 (³J_{HH}=6.7 Hz, 1H, iPr-CH), m 6.21 (2H, Cp-H), m 6.32 (2H, Cp-H). ¹¹⁹Sn (186 MHz, C₆D₆) (FIG. 10): s 63.9 ppm.

Compounds of Formula I could have improved thermal stability and surface reactivity compared to those known in the art, which may result in improved ALD films. Poor thermal stability can hinder reactivity of the precursor with the substrate surface during ALD deposition, that is, the precursor should not decompose prior to ALD deposition. In contrast to ALD, in CVD processes, high energy and temperature are used to react the precursors at process temperature. Then, the already-reacted precursors react on the substrate. Because the CVD process uses substantially larger energy and breaks apart the precursors prior to the reaction, the reactivity of the precursors is not as important in CVD processes as in ALD processes.

### Negative Resist Deposition

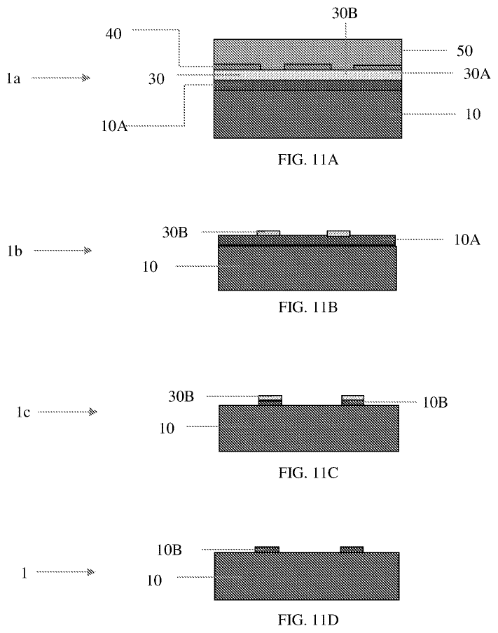

FIGS. 11A-11D show an exemplary process of negative resist deposition using a compound of Formula I. A multi-layer substrate 10 is provided. In the illustrated example, layer 10A is the only layer of the substrate that is to be patterned. A layer of photosensitive material 30 including the compound of Formula I is subsequently deposited onto the layer 10A. Then, mask(s) 40 is selectively applied over portions of the layer of photosensitive material 30 such that unexposed portions 30A of the layer of photosensitive material 30 are covered by the mask 40 and exposed portions 30B of the layer of photosensitive material 30 are not covered by the mask 40. Lastly, in the illustrated example, a mask glass layer 50 is applied over the mask(s) 40 and layer of photosensitive material 30. Thus, forming a deposited intermediate part la as shown in FIG. 11A.

The deposited intermediate part 1a is then illuminated with extreme ultraviolet (EUV) light through the mask(s) 40 resulting in a photolytic cleavage of Sn-C bonds that promotes cross-linking. After illumination, the deposited intermediate part 1a is baked to densify the SnO₂ layers. Then, the glass mask 50 is removed.

A development step is illustrated in FIG. 11B. During the development step, the unexposed portion 30A of the layer of photosensitive material 30 that was not exposed to EUV light during illumination is removed such that only the exposed portion 30B of the layer of photosensitive material 30 remains. The unexposed portion 30B is positioned over the layer 10A of the multi-layer substrate 10, as shown in FIG. 11B. Thus, forming a developed intermediate product 1b as shown in FIG. 11B.

During the etching step, shown in FIG. 11C, the layer 10A of the multi-layer substrate 10 is etched to produce a desired pattern. The etching results in layer 10B, which is covered by the exposed portion 30B of the layer of photosensitive material 30. Thus, forming an etched intermediate product 1c as shown in FIG. 11C.

Lastly, the exposed portion 30B of the layer of photosensitive material 30 is removed, leaving behind the desired pattern. FIG. 11D illustrates that resulting pattern. Thus, forming the product 1 as shown in FIG. 11D.

Compounds of Formula I are particularly advantageous for negative resist deposition methods because tuning the bond energy of Sn-C by using allyl or vinyl ligands improves performance of the Sn photosensitive materials. It is contemplated that photolytic cleavage of Sn-C bonds during exposure to EUV light will promote cross-linking, thus making these materials superior over those known in the art.

### Multistage Distillation

From theoretical modeling of the activation energy required to strip off ligands from molecules via hydrolysis reaction, a wide range in activation energies between molecules is observed. Hence differences in reactivity are observed. This shows the likelihood that the molecule would be a highly reactive molecule for the formation of SnO₂ when the activation energy is low, but this value also shows that the molecule might be more prone to decomposition and reaction during the synthesis and purification processes. Accordingly, obtaining purity of compounds within the scope of Formula I will be difficult to obtain, especially assay purity of greater than 95% or even greater than 99%.

However, using multistage vacuum distillation can obtain greater than 95% or even greater than 99% assay purity for compounds in the scope of Formula I. Various forms of multistage distillation are known in the chemical manufacturing industry, but have not been employed for the purification of organometallic materials that include compounds of Formula I.

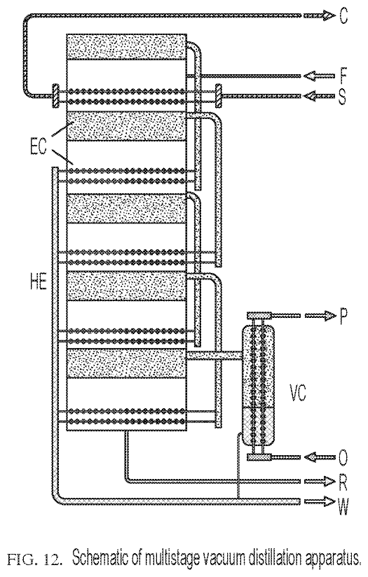

As illustrated by the schematic shown in FIG. 12, multiple-effect or multistage distillation (MED) is a distillation process often used for sea water desalination. It consists of multiple stages or “effects”. (In schematic in FIG. 14 the first stage is at the top. Top areas of each stage are vapor, bottom areas of each stage are liquid feed material. The material running through the pipe along the left side of the figure and in the bottom of the VC is condensate. It is not shown how feed material enters other stages than the first, however those should be readily understood. F—feed in. S—heating steam in. C—heating steam out. W—purified material (condensate) out. R—waste material out. O—coolant in. P—coolant out. VC is the last-stage cooler.) In each stage the feed material is heated by steam in tubes. Some of the feed material evaporates, and this steam flows into the tubes of the next stage, heating and evaporating more of the distillate. Each stage essentially reuses the energy from the previous stage.

The apparatus can be seen as a sequence of closed spaces separated by tube walls, with a heat source at one end and a heat sink at the other. Each space is at pressure below atmospheric conditions via vacuum. Each space consists of two communicating subspaces, the exterior of the tubes of stage n and the interior of the tubes in stage n+1. Each space has a lower temperature and pressure than the previous space, and the tube walls have intermediate temperatures between the temperatures of the fluids on each side. The pressure in a space cannot be in equilibrium with the temperatures of the walls of both subspaces; it has an intermediate pressure. As a result, the pressure is too low or the temperature too high in the first subspace, and the feed material evaporates. In the second subspace, the pressure is too high or the temperature too low, and the vapor condenses. This carries evaporation energy from the warmer first subspace to the colder second subspace. At the second subspace the energy flows by conduction through the tube walls to the colder next space.

1. An organometallic compound of Formula I:
(R)ₓSn(A)₄₋ₓ Formula I
wherein:
R is substituted Cpor a non-cyclic unsaturated hydrocarbon having 2 to 10 carbon atoms;
A is NR¹R², OR³, pyrrolidinyl, or pyrrolyl, or halide;
R¹ and R² are each independently selected from the group consisting of an alkyl group having from 1 to 10 carbon atoms, an aryl group, and an acyl group;
R³ is selected from the group consisting of an alkyl group having 1 to 10 carbon atoms and an aryl group;
x is an integer from 1 to 3;
when A is OR³, then R is a vinyl group;
when R is a vinyl group, x is 3, and A is NR¹R², then at least one of R¹ and R² is not Et; and
substituted Cp has the formula C₅R¹²R¹³R¹⁴R¹⁵R¹⁶, wherein at least one of R¹², R¹³, R¹⁴, R¹⁵, R¹⁶is H and at least one other of R¹², R¹³, R¹⁴, R¹⁵, R¹⁶ is an alkyl group having from 1 to 10 carbon atoms.

2. The organometallic compound according to claim 1, wherein x is 1or 2.

3. The organometallic compound according to claim 1, wherein R is an allyl or vinyl group.

4. The organometallic compound according to claim 1, wherein R is a straight-chain unsaturated hydrocarbon.

5. The organometallic compound according to claim 1, wherein R is an allyl group having the general formula: CR⁴R⁵CR⁶═CR⁷R⁸, wherein R⁴, R⁵, R⁶, R⁷, and R⁸ are each independently selected from the group consisting of H and alkyl groups having from 1 to 4 carbon atoms

6. The organometallic compound according to claim 1, wherein R is a vinyl group having the general formula: CR⁹═CR¹⁰R¹¹, wherein R⁹, R¹⁰, and R¹¹are each independently selected from the group consisting of H and alkyl groups having from 1 to 4 carbon atoms.

7. The organometallic compound according to claim 1, wherein R is substituted Cp.

8. The organometallic compound according to claim 1, wherein x is 2.

9. The organometallic compound according to claim 1, wherein A is NR¹R².

10. The organometallic compound according to claim 9, wherein R¹ and R² are independently selected from an alkyl group having from 1 to 4 carbon atoms.

11. The organometallic compound according to claim 10, wherein R¹ is Me or Et.

12. The organometallic compound according to claim 10, wherein R² is Me or Et.

13. The organometallic compound according to claim 9, wherein R¹ and R² are different.

14. The organometallic compound according to claim 1, wherein A is OR³.

15. The organometallic compound according to claim 14, wherein R³ is an alkyl group having from 1 to 4 carbon atoms.

16. The organometallic compound according to claim 15, wherein R³ is Me, Et, or ^{t}Bu.

17. The organometallic compound according to claim 1, wherein A is pyrrolyl.

18. The organometallic compound according to claim 1, wherein A is pyrrolidinyl.

19. The organometallic compound according to claim 1, wherein when R is a vinyl group and A is NR¹R², then x is 1 or 2.

20. The organometallic compound according to claim 1, wherein the organometallic compound is selected from the group consisting of (CH₂═CHCH₂)Sn(NMe₂)₃, (CH₂═CH)Sn(Pyrrolidinyl)₃, (CH₂═CHCH₂)₂Sn(NMe₂)₂, (CH₂═CHCH₂)₂Sn(NEt₂)₂, (CH₂═CHCH₂)₂Sn(NEtMe)₂, (CH₂═CHCH₂)₂Sn(Pyrrolidinyl)₂, (CH₂═CH)₂Sn(NMe₂)₂, (CH₂═CH)₂Sn(NEt₂)₂, (CH₂═CH)₂Sn(NEtMe)₂, (CH₂═CH)₂Sn(Pyrrolidinyl)₂, (CH₂═CH)₂Sn(OMe)₂, (CH₂═CH)₂Sn(OEt)₂, (CH₂═CH)₂Sn(O^{t}Bu)₂, (CH₂═CHCH₂)₃Sn(NMe₂), and (CH₂═CH)₃Sn(Pyrrolidinyl).
